(19) United States
(12) Patent Application Publication
(10) Pub. No.: US 2007/0166878 A1
(43) Pub. Date: Jul. 19, 2007

(54) PACKAGE STRUCTURE AND METHOD FOR FABRICATING THE SAME

(76) Inventor: Chiu-Feng Li, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/556,206

(22) Filed: Nov. 3, 2006

(30) Foreign Application Priority Data
Jan. 16, 2006 (TW) 095101614

(51) Int. Cl. H01L 21/00

(52) U.S. Cl. 438/106; 438/460; 438/113

(57) ABSTRACT

A method for forming a package structure is disclosed. First, a wafer is provided, in which the front surface of the wafer includes a plurality of die areas and a plurality of scribe lines. Next, a plurality of cavities is formed on a back surface of the wafer with respect to the die areas, in which each die area includes a cavity. A dicing process is performed thereafter to dice the wafer along the scribe lines for forming a plurality of dies. A heat dissipating device has at least one portion disposed in the cavity of each die thereafter.

### BACKGROUND OF THE INVENTION

1. Field of the Invention

The invention relates to a method for fabricating package structures.

2. Description of the Prior Art

As the demand of smaller, more functional and complex PDAs, cellular phones, CPUs, and memory modules increases each day, the development of semiconductors also moves toward a direction of higher density packaging. Among many popular package structures, a flip chip (FC) structure with the characteristics of rapid cooling, low inductance, multi-terminal, and small size has been used most commonly in favor of others.

Please refer to FIG. 1. FIG. 1 illustrates a flip chip package 30 according to the prior art. As shown in FIG. 1, the flip chip package 30 includes a die 32 and a plurality of bonding pads (not shown) disposed on an active surface 34 of the die 32. The flip chip package 30 also includes a substrate 36, such as a multi-layer circuit board, in which the substrate 36 includes an upper surface 38 and a plurality of solder pads (not shown) disposed on the upper surface 38.

During the packaging process, the active surface 34 of the die 32 is facing toward the upper surface 38 of the substrate 36, such that the bonding pads are positioned corresponding to the location of the solder pads. Subsequently, a plurality of bumps 42 is disposed between the bonding pads and the solder pads for establishing a physical and electrical connection between the pads. The flip chip package 30 may also include an under bump metallurgy layer (not shown) between the bonding pads and the bumps 42. Depending on the fabrication of the package, the under bump metallurgy layer can be a bonding layer, a barrier layer, a wetting layer, or a conductive layer. Preferably, the die 32 includes at least a very large scale integration (VLSI) circuit or at least an ultra large scale integration (ULSI) circuit formed therein, in which the VLSI circuits or ULSI circuits are electrically connected to the bonding pads and the bumps 42.

The flip chip package 30 also includes an underfill 44 disposed in the gap between the substrate 36 and the die 32 to protect the flip chip package 30 and release the stress from the spot where the bumps 42 is connected. The flip chip package 30 also includes a plurality of solder pads 46 disposed on a lower surface 45 of the substrate 36, and a plurality of solder balls 48 connected to each of the solder pads 46. Additionally, the back surface 47 of the die 32 includes a heat dissipating device 49 disposed thereon for dissipating the heat generated by the die 32. The heat dissipating device 49 can be a heat sink, a heat spreader, or a fan.

Unfortunately, despite the fact that the heat dissipating device 49 is attached directly on the back surface of the die 32, the electrical circuits located close to the active surface 34 within the die 32 are still too far from the heat dissipating device 49, thus increasing the heat dissipating time for the die and reducing the performance of the flip chip package 30. Additionally, by using only heating gel to attach the heat dissipating device 49 onto the back surface 47 of the die 32, the adhesion between the two units is poor.

### SUMMARY OF THE INVENTION

It is an objective of the present invention to provide a method for fabricating a package structure for solving the aforementioned problems.

A method for forming a package structure is disclosed. First, a wafer is provided, in which the front surface of the wafer includes a plurality of die areas and a plurality of scribe lines. Next, a plurality of cavities is formed on a back surface of the wafer with respect to the die areas, in which each die area includes a cavity. A dicing process is performed thereafter to dice the wafer along the scribe lines for forming a plurality of dies. A heat dissipating device has at least one portion disposed in the cavity of each die thereafter.

Preferably, by forming a cavity in the back surface of each die after dicing a wafer and disposing at least one portion of a heat dissipating device into each cavity, the present invention is able to reduce the heat transfer distance for the dies and increase the dissipating ability for the package structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a flip chip package according to the prior art.

FIGS. 2-7 illustrate a method for fabricating a package structure according to the present invention.

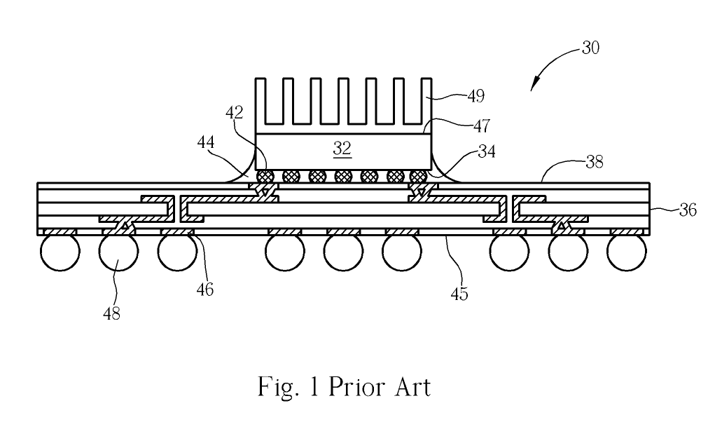

### DETAILED DESCRIPTION

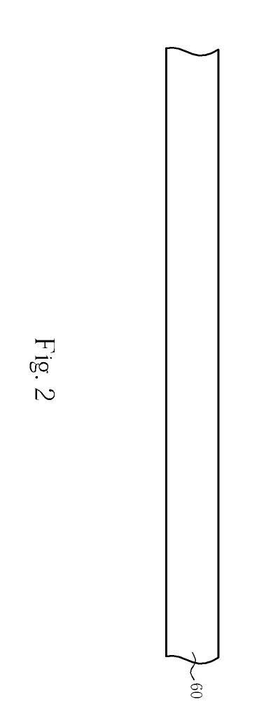

Please refer to FIGS. 2-7. FIGS. 2-7 illustrate a method for fabricating a package structure according to the present invention. As shown in FIG. 2, a wafer 60 having completed very large scale integration (VLSI) or ultra large scale integration (ULSI) process is provided. The front surface of the wafer 60 includes a plurality of die areas (not shown), a plurality of horizontal scribe lines (not shown), and a plurality of vertical scribe lines (not shown). The scribe lines are used to separate the die areas.

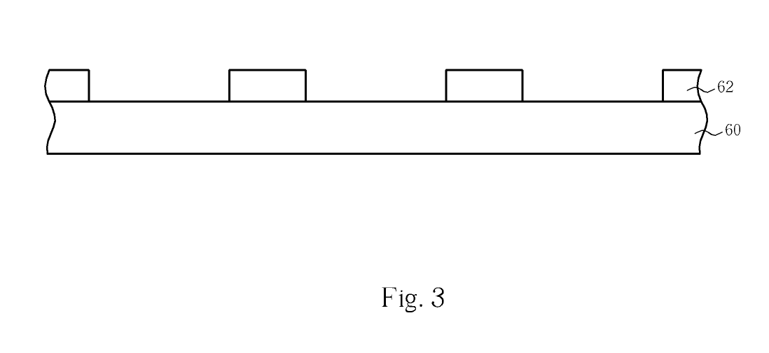

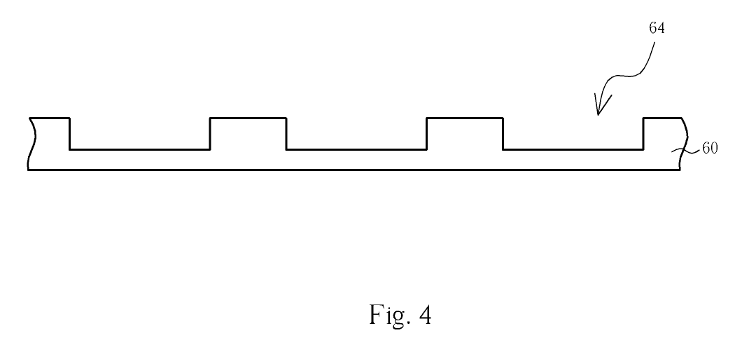

As shown in FIG. 3, a patterned mask 62, such as a patterned photoresist is disposed on the back surface of the wafer 60 for defining the position of a plurality of cavities with respect to the die areas. As shown in FIG. 4, an etching process is performed to form a plurality of cavities 64 on the back surface of the wafer 60 with respect to each die area. Preferably, the etching process can be a wet etching process or a plasma etching process.

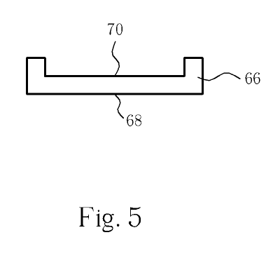

As shown in FIG. 5, the wafer 60 is diced along the scribe lines to form a plurality of dies 66, in which only one die is shown in the figure, and each die 66 includes an active surface 68 and a back surface 70.

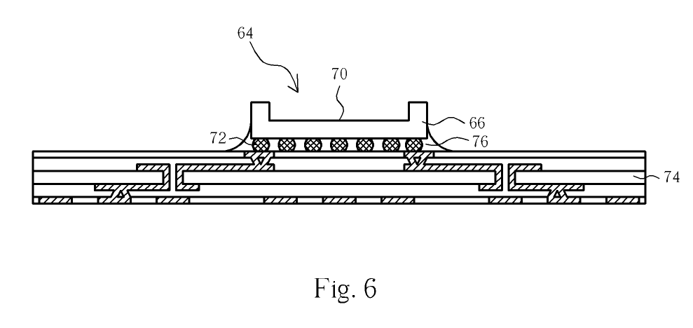

Next, as shown in FIG. 6, a packaging process, preferably a flip chip packaging process is performed to form a plurality of bumps 72 on the active surface 68 of the die 66. The bumps 72 are used to electrically connect each die 66 and the surface of a substrate 74. After a reflow process is performed, an underfull 76 is disposed between the die 66, the bumps 72, and the substrate, in which the underfull 76 serves to attach the die 66 onto the surface of the substrate 74.

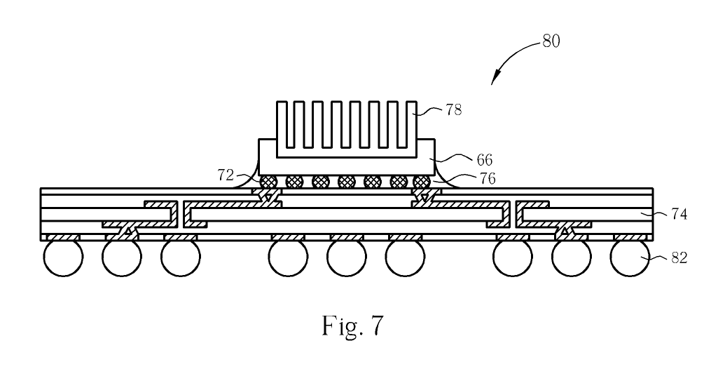

As shown in FIG. 7, a thermal inductive material (not shown) is disposed into the cavity 64, and a heat dissipating device 78 has at least one portion disposed in the cavity 64 thereafter to complete a flip chip package 80. The heat dissipating device 78 can be a heat sink, a heat spreader, or a fan. Subsequently, the flip chip package 80 is disposed in a nitrogen oven and a curing process is performed to adhere the at least one portion of the heat dissipating device 78 onto the surface of the cavity 64. Depending on the demand of the fabrication process, a plurality of solder balls 82 can be disposed on the bottom of the substrate 74 thereafter.

It should be noted that by forming a cavity 64 on the back surface 70 of each die 66 after dicing the wafer 60 and disposing at least one portion of a heat dissipating device 78 into each cavity 64 thereafter, the present invention is able to reduce the distance between the heat dissipating device 78 and the die 66. In other words, by using the cavity 64 to reduce the dissipating path between the heat dissipating device 78 and the heat source, the heat dissipation of the package can be improved significantly.

According to another embodiment of the present invention, after forming a plurality of cavities 64 on the back surface of the wafer 60, the bumps 72 can be placed on the front surface of the wafer 60 before dicing the wafer 60 along the scribe lines to form a plurality of dies 66. The resulting die 66 will therefore carry a plurality of bumps 72 thereon. Next, a thermal inductive material is disposed in each cavity 64, in which the thermal inductive material is used to adhere the at least one portion of the heat dissipating device 78 into the cavity 64. The die 66 having bumps 72 thereon is then disposed on the substrate 74, and an underfill 76 is disposed between the die 66, the bumps 72, and the substrate 74 to complete the fabrication of the flip chip package 80.

As shown in FIG. 7, a flip chip package 80 fabricated by the aforementioned process is disclosed. The flip chip package 80 includes a substrate 74 and at least a die 66 having a cavity 64 therein, and at least one portion of a heat dissipating device 78 disposed in the cavity 64. The die 66 is disposed on the substrate 74 and electrically connected to the substrate 74. Preferably, the substrate 74 is a flip chip substrate, and the flip chip package 80 includes a plurality of bumps 72 formed between the die 66 and the substrate 74. The flip chip package 80 also includes an underfill 76 disposed between the die 66, the bumps 72, and the substrate 74, and a thermal inductive material disposed in the cavity 64 for adhering the heat dissipating device 78 and the die 66.

In contrast to the conventional means of forming packages having heat dissipating device, the present invention first forms a cavity on the back surface of each die after dicing a wafer into a plurality of dies, and disposes at least one portion of a heat dissipating device into each cavity. Thereby, the distance of heat transfer between the heat dissipating device and the die is reduced, and the heat dissipating ability of the package structure is increased significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming package structures, comprising:
providing a wafer, wherein a front surface of the wafer comprises a plurality of die areas and a plurality of scribe lines;
forming a plurality of cavities on a back surface of the wafer with respect to the die areas, wherein each die area comprises a cavity;
dicing the wafer along the scribe lines for forming a plurality of dies; and
disposing at least one portion of a heat dissipating device into the cavity of each die.

2. The method for forming package structures of claim 1 further comprising performing an etching process for forming the cavities.

3. The method for forming package structures of claim 2, wherein the etching process comprises a wet etching process or a plasma etching process.

4. The method for forming package structures of claim 2 further comprising forming a patterned mask before forming the cavities for defining the location of the cavities on the back surface of the wafer with respect to the die areas.

5. The method for forming package structures of claim 4, wherein the patterned mask is a patterned photoresist.

6. The method for forming package structures of claim 1 further comprising dispensing a thermal inductive material into the cavities before disposing the at least one portion of the heat dissipating device into the cavity of each die.

7. The method for forming package structures of claim 6 further comprising performing a curing process after disposing the at least one portion of the heat dissipating device into the cavity of each die.

8. The method for forming package structures of claim 1 further comprising performing a packaging process after disposing the at least one portion of the heat dissipating device into the cavity of each die.

9. The method for forming package structures of claim 8, wherein the packaging process comprises a flip chip packaging process.

10. The method for forming package structures of claim 1 further comprising forming a plurality of bumps on a surface of the die without having any of the cavities for electrically connecting the die and the surface of a substrate.

11. The method for forming package structures of claim 10 further comprising disposing an underfill between the die, the bumps, and the substrate after forming the plurality of bumps on the surface of the die.
